(19) United States
(12) Patent Application Publication
(10) Pub. No.: US 2025/0079349 A1
(43) Pub. Date: Mar. 6, 2025

(54) ANTENNA DIODE INTEGRATION WITH BACKSIDE BACK END OF THE LINE NETWORK

(71) Applicant: INTERNATIONAL BUSINESS MACHINES CORPORATION, ARMONK, NY (US)

(72) Inventors: Ruilong Xie, Niskayuna, NY (US); Terence B. Hook, Jericho Center, VT (US); Kisik Choi, Watervliet, NY (US); HUIMEI ZHOU, Albany, NY (US)

(21) Appl. No.: 18/461,636

(22) Filed: Sep. 6, 2023

(51) Int. Cl. H01L 23/66; H01L 23/498; H01L 27/07; H01L 29/08; H01L 29/66; H01L 29/861; H01Q 1/22; H01Q 1/50

(52) U.S. Cl. CPC H01L 23/66; H01L 23/49822; H01Q 1/2283; H01Q 1/50; H10D 8/00; H10D 30/024; H10D 62/154; H10D 62/158; H10D 84/811; H01L 2223/6616; H01L 2223/6677

(57) ABSTRACT

The present disclosure describes an illustrative semiconductor IC device that includes an antenna diode that drains electrical charge build up created during backside BEOL network fabrication processes. The semiconductor IC device includes an active semiconductor IC device upon which the backside BEOL network is to be fabricated and a handler semiconductor device that includes a diode doped region. Charge build up that may occur during the fabrication of the backside BEOL network may be dissipated through the diode doped region. As such, parasitic charge build up that may damage the semiconductor IC device is limited, thereby increasing yield of, and thereby limiting semiconductor IC device failure.

### BACKGROUND

The present disclosure relates to fabrication methods and resulting structures for semiconductor devices. More specifically, the present disclosure relates to fabrication methods and resulting semiconductor integrated circuit (IC) devices that include an antenna diode that drains electrical charge build up.

A backside back end of line (BEOL) network, such as a backside power distribution network (BSPDN) may include signal wires for signal routing and power for providing static potential (e.g., VDD, VSS, etc.). The backside BEOL network allows for the decoupling of signal routing and/or power routing and/or allows to divide or split power wires and/or signal wires between both the frontside and backside of the semiconductor IC device. By incorporating the backside BEOL network, routing congestion may be reduced, which may lead to further semiconductor IC device scaling. For example, semiconductor IC devices that incorporate a backside BEOL network can result in a 30% area reduction and improved current-resistance (IR) drop compared to typical semiconductor IC devices that include solely a frontside BEOL network.

However, the backside BEOL network may be difficult to manufacture as it requires multi-layer components to connect the backside wires with active devices included in the semiconductor IC device. Typically, to fabricate the backside BEOL, a series of dielectric layers with various wires therein are fabricated. Openings and/or trenches may be formed within these dielectric layers as they are formed and conductive material(s) may be deposited therein, which may form wires, VIAs, or the like. These openings and/or trenches may be formed by plasma etching processes. Plasma etching can lead to charge buildup within the semiconductor IC device. If the charge buildup is sufficiently high and occurs within a wire that is connected to a gate, the gate isolation (e.g., oxide or the like) associated therewith might be damaged, reducing yield, causing semiconductor IC device failure, or the like.

### SUMMARY

In an embodiment of the present disclosure, a semiconductor integrated circuit (IC) device is presented. The semiconductor IC device includes a handler semiconductor IC device and an active semiconductor IC device. The handler semiconductor IC device includes a diode doped region. The active semiconductor IC device includes a backside source/drain (S/D) contact connected to a S/D region and a backside diode contact connected to the diode doped region. Charge build up that may occur during backside fabrication operations on the active semiconductor IC device may be dissipated through the diode doped region. As such, parasitic charge build up that may damage the semiconductor IC device is limited, thereby increasing yield of, and thereby limiting semiconductor IC device failure.

In an example, the active semiconductor IC device further includes a frontside back end of line (BEOL) network with a charge collector wire connected to the diode doped region. The charge collector wire may collect the charge build up that may occur during backside fabrication operations on the active semiconductor IC device so that the parasitic charge can be dissipated through the diode doped region.

In an example, the active semiconductor IC device further includes a frontside gate contact connected to the diode doped region through the charge collector wire. Charge build up that may occur during backside fabrication operations on the active semiconductor IC device may be collected upon the frontside gate contact and dissipated through charge collector wire and further through the diode doped region.

In an example, the active semiconductor IC device further includes a frontside S/D contact connected to the diode doped region through the charge collector wire. Charge build up that may occur during backside fabrication operations on the active semiconductor IC device may be collected upon the frontside S/D contact and dissipated through charge collector wire and further through the diode doped region.

In an example, the active semiconductor IC device further includes a first contact pad connected to the charge collector wire. The first contact pad may be utilized to electrically connect or bond the active semiconductor IC device to the handler semiconductor IC device.

In an example, the handler semiconductor IC device further includes a second contact pad connected to the diode doped region. The second contact pad may be utilized to electrically connect or bond the handler semiconductor IC device to the active semiconductor IC device.

In an example, electrical charge within the charge collector dissipates through the diode doped region. As such, parasitic charge build up that may damage the semiconductor IC device is limited, thereby increasing yield of, and thereby limiting semiconductor IC device failure.

In an example, the active semiconductor IC device further includes an electrical pathway connected to the charge collector wire and connected to the first contact pad. The electric pathway includes a plurality of conductive wires and a plurality of conductive vias. The electrical pathway provides a pathway through the active semiconductor IC device from the backside to the frontside thereof so that the parasitic electrical charge may pass therethrough into the diode doped region.

In an example, the handler semiconductor IC device further includes a diode contact between the second contact pad and the diode doped region. The diode contact, therefore, may pass the parasitic electrical charge therethrough into the diode doped region.

In an embodiment of the present disclosure, a semiconductor integrated circuit (IC) device is presented. The semiconductor IC device includes an antenna diode within a handler semiconductor IC device and an active semiconductor IC device. The antenna diode includes a diode doped region. The active semiconductor IC device includes a backside source/drain (S/D) contact connected to a S/D region and a backside diode contact connected to the diode doped region. Charge build up that may occur during backside fabrication operations on the active semiconductor IC device may be dissipated through the diode doped region. As such, parasitic charge build up that may damage the semiconductor IC device is limited, thereby increasing yield of, and thereby limiting semiconductor IC device failure.

In an example, the active semiconductor IC device further includes a frontside back end of line (BEOL) network with a charge collector wire connected to the diode doped region. The charge collector wire may collect the charge build up that may occur during backside fabrication operations on the active semiconductor IC device so that the parasitic charge can be dissipated through the diode doped region.

In an example, the active semiconductor IC device further includes a frontside gate contact connected to the diode doped region through the charge collector wire. Charge build up that may occur during backside fabrication operations on the active semiconductor IC device may be collected upon the frontside gate contact and dissipated through charge collector wire and further through the diode doped region.

In an example, the active semiconductor IC device further includes a frontside S/D contact connected to the diode doped region through the charge collector wire. Charge build up that may occur during backside fabrication operations on the active semiconductor IC device may be collected upon the frontside S/D contact and dissipated through charge collector wire and further through the diode doped region.

In an example, the active semiconductor IC device further includes a first contact pad connected to the charge collector wire. The first contact pad may be utilized to electrically connect or bond the active semiconductor IC device to the handler semiconductor IC device.

In an example, the handler semiconductor IC device further includes a second contact pad connected to the diode doped region. The second contact pad may be utilized to electrically connect or bond the handler semiconductor IC device to the active semiconductor IC device.

In an example, electrical charge within the charge collector dissipates through the antenna diode. As such, parasitic charge build up that may damage the semiconductor IC device is limited, thereby increasing yield of, and thereby limiting semiconductor IC device failure.

In an example, the active semiconductor IC device further includes an electrical pathway connected to the charge collector wire and connected to the first contact pad. The electric pathway includes a plurality of conductive wires and a plurality of conductive vias. The electrical pathway provides a pathway through the active semiconductor IC device from the backside to the frontside thereof so that the parasitic electrical charge may pass therethrough into the diode doped region.

In an example, the handler semiconductor IC device further includes a diode contact between the second contact pad and the diode doped region. The diode contact, therefore, may pass the parasitic electrical charge therethrough into the diode doped region.

In an embodiment of the present disclosure, a semiconductor integrated circuit (IC) device fabrication method is presented. The method includes bonding a handler semiconductor IC device to an active semiconductor device. The method includes forming a backside back end of the line (BEOL) network over a backside of the active semiconductor device. The method further includes dissipating electrical charge through a frontside BEOL network of the active semiconductor device and further through the handler semiconductor IC device. In this manner, parasitic charge build up that may damage the semiconductor IC device is limited, thereby increasing yield of, and thereby limiting semiconductor IC device failure.

In an example, the electrical charge is dissipated through a diode doped region within the handler semiconductor IC device. The diode doped region may accumulate the electrical charge and may further ultimately pass the electrical charge out of the semiconductor IC device.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross section view of an active semiconductor IC device that includes one or more active devices or active regions, at a particular fabrication stage, according to one or more embodiments of the disclosure.

FIG. 2 depicts a cross section view of a handler semiconductor IC device at a particular fabrication stage, according to one or more embodiments of the disclosure.

FIG. 3 depicts a cross section view of the active semiconductor IC device at a subsequent fabrication stage, according to one or more embodiments of the disclosure.

FIG. 4 depicts a cross section view of the handler semiconductor IC device at a subsequent fabrication stage, according to one or more embodiments of the disclosure.

FIG. 5 depicts a cross section view of a semiconductor IC device that includes an antenna diode, according to one or more embodiments of the disclosure.

FIG. 6 depicts a cross section view of the semiconductor IC device of FIG. 5 at a subsequent fabrication stage, according to one or more embodiments of the disclosure.

FIG. 7 depicts a cross section view of the semiconductor IC device of FIG. 6 at a subsequent fabrication stage, according to one or more embodiments of the disclosure.

FIG. 8 depicts a flowchart of a method of fabricating an active semiconductor IC device that includes one or more active devices or active regions, according to one or more embodiments of the disclosure.

FIG. 9 depicts a flowchart of a method of fabricating a handler semiconductor IC device, according to one or more embodiments of the disclosure.

FIG. 10 depicts a flowchart of a method of fabricating a semiconductor IC device that includes an antenna diode, according to one or more embodiments of the disclosure.

### DETAILED DESCRIPTION

The present disclosure describes an illustrative semiconductor IC device that includes an antenna diode that drains electrical charge build up created during backside BEOL network fabrication processes. The semiconductor IC device includes an active semiconductor IC device and a handler semiconductor device. The active semiconductor IC device includes a frontside BEOL network with a charge collector therein. The active semiconductor IC device further includes an active region where one or more active devices, logic devices, or the like, such as field effect transistors (FETs), are fabricated and still further includes a backside BEOL network. A respective gate from one or more FETs within the active region are electrically connected to the charge collector. One or more conductive pathways, respectively, may connect the backside BEOL network to the charge collector and the charge collector to the frontside of the active semiconductor IC device.

The handler semiconductor IC device includes a diode doped region and an intrinsic substrate. The handler semiconductor IC device is attached to the active semiconductor IC device and the diode doped region is electrically connected to the charge collector by the respective conductive pathway(s).

During fabrication of the backside BEOL network, a potential (e.g., VDD) may be applied to the handler semiconductor IC device and an antenna diode may be effectively formed by the diode doped region, the intrinsic substrate, and the potential. Charge build up that may occur during the fabrication of the backside BEOL network is effectively collected on the charge collector and dissipates through the antenna diode. As such, parasitic charge build up that may damage the gate isolation of the respective gate(s) is limited, thereby increasing yield of, and thereby limiting semiconductor IC device failure.

The flowcharts and cross-sectional diagrams in the drawings illustrate a method of fabricating semiconductor IC device, such as a processor, FPGA, memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, for some transistor architectures, integration of the transistors with a backside BEOL network is one of the key challenges to providing increasing packaged IC device densities and performance increases. By incorporating the BEOL network into the semiconductor IC device, there may be a logical and/or functional separation between electrical signal routing and electrical power routing through the semiconductor IC device which may ease routing congestion in some applications. Currently, there is a need to dissipate charge build up that occurs during the fabrication of the backside BEOL network and to limit the ill effects thereof (e.g., gate isolation damage, reduction of device yield, or the like).

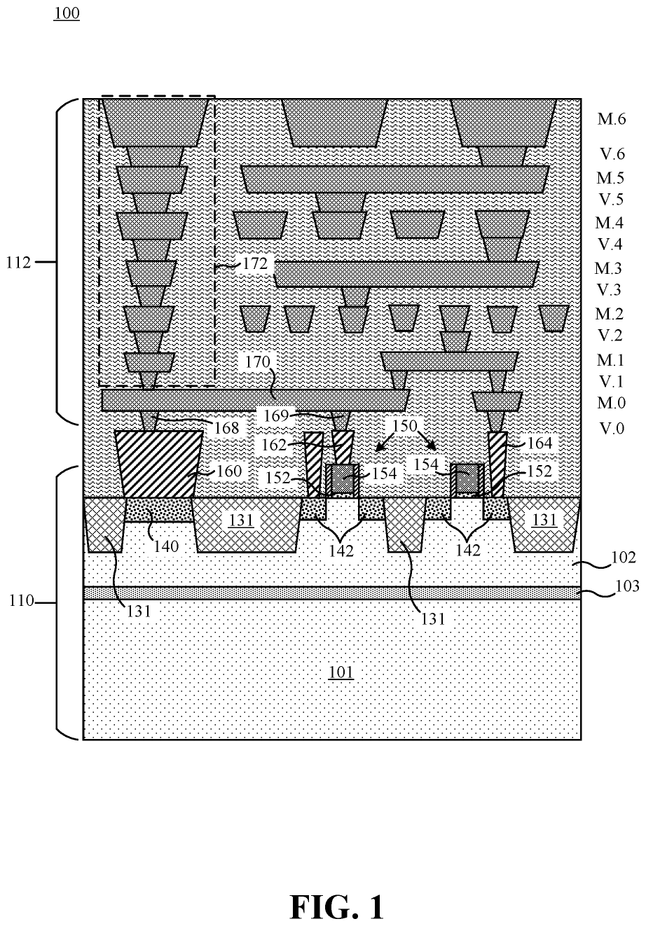

Referring now to FIG. 1, which depicts an illustrative active semiconductor IC device 100 that includes one or more active regions that include respective active devices, such as FETs 150, at a particular fabrication stage.

At the present fabrication stage, active semiconductor IC device 100 includes three sections: a front-end-of-line (FEOL) 110 section, a frontside back-end-of-line (BEOL) network 112, and a section that connects those two together, the middle-of-line (MOL) section. The FEOL 110 includes the active devices of active semiconductor IC device 100, such as FETs 150. The frontside BEOL network 112 includes interconnects, wiring, and material(s) to prevent undesired current flow between conductive features therein. The MOL includes interconnects between the FEOL 110 and BEOL network 112 and further includes material(s) to prevent the diffusion of frontside BEOL network 112 conductive material(s) into FEOL active devices.

The FEOL 110 includes the active devices, such as FETs 150, a substrate structure, shallow trench isolation (STI) regions 131 within the substrate structure that separate the active devices, and doped region 140. In the various embodiments of the present invention, the active devices include one or more conductive features, such as a metal gate, doped region(s), or the like that are connected to one or more wires within the frontside BEOL network 112. For example, a conductive or metal gate 154 of one or more FETs 150 is connected to charge collector wire 170, or a particular conductive wire within the frontside FEOL network 112.

The one or more FETs 150 include the gate 154, a gate insulator 152 below the gate 154, source/drain (S/D) regions 142, and a channel region between the S/D regions 142. The one or more FETs 150 may have a structural architecture now known or later developed. For example, the FETs 150 may be FinFETs, gate all around (GAA) FETs, fork-sheet FETs, nanosheet FETs, nanowire FETs, or the like. The active devices, such as one or more FETs, may be fabricated upon a substrate structure.

The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in semiconductor IC device fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any other suitable material(s) than those listed above with regards to the substrate structure and the etch stop layer 103 may be a dielectric material with etch selectivity to one or both of the upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 102 may be composed of Si and may be epitaxially grown from the top surface of etch stop layer 103.

FETs 150 may be formed over and/or within the substrate structure using FET fabrication processes. For example, FinFET fabrication processes, such as fin formation, STI region 131 formation, sacrificial gate structure formation, gate spacer formation, doping ion implantation to form S/D regions 142 and doped region 140, interlayer dielectric (ILD) formation, sacrificial gate structure removal, replacement gate structure formation to form gate insulator 152 and gate 154, ILD formation, and frontside contact formation to form frontside contact 160, frontside S/D contact 164, and frontside gate contact 162, and/or the like may be utilized to fabricate the depicted active semiconductor IC device 100. In another example, nanolayer FET fabrication processes such as alternating sacrificial layer formation, sacrificial layer stack formation, STI region 131 formation within the recessed substrate, sacrificial gate structure formation, gate spacer formation, substrate structure recess, sacrificial nanolayer independent, inner spacer formation, S/D region 142 and doped region 140 formation, sacrificial gate structure removal, sacrificial nanolayer removal, replacement gate structure formation to form gate insulator 152 and gate 154, ILD formation, and frontside contact formation to form frontside contact 160, frontside S/D contact 164, and frontside gate contact 162, and/or the like may be utilized to fabricate an alternative semiconductor IC device.

The S/D regions 142 forms either a source or a drain, respectively, of a respective FET 150 and is connected to respective one or more channels of the respective FET 150 (e.g., the depicted portion of the substrate structure between the S/D region 142, or the like). The S/D region 142 and the doped region 140 is composed of a semiconductor material and a dopant. As used herein, a “source/drain” region can be a source region or a drain region depending on subsequent wiring and application of voltages during operation of the transistor. The semiconductor material that provides each of the S/D region 142 and doped region 140 is composed of one of the semiconductor materials mentioned above for the semiconductor structure. The semiconductor material that provides the S/D region 142 and doped region 140 can be compositionally the same, or compositionally different the substrate structure. The dopant that is present in the S/D region 142 and/or doped region 140 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D regions 142 and the doped region 140 can have a dopant concentration of from 4×10²⁰ atoms/cm³ to 3×10²¹ atoms/cm³.

The one or more S/D regions 142 and the doped region 140 may be epitaxially grown or formed. In some examples, the S/D region 142 and the doped region 140 are formed by in-situ doped epitaxial growth. The use of an in-situ doping process is merely an example. For instance, one may instead employ an ex-situ process to introduce dopants. Other doping techniques can be used to incorporate dopants. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques.

The gate insulator 152 is formed from a dielectric layer, such as an oxide, that allows the gate 154 to modulate the conductance of the channel. The threshold voltage of FET 150 is related to the gate voltage, and the gate leakage effect is dominant in these systems. The gate insulator 152 is made relatively thinner to maintain performance and control short channel effects. The gate isolation may be formed by forming an interfacial layer on the gate spacers, on the channel nanolayers, etc. that are interior to and/or upon the respective surfaces interior to the opening created by the removal of the sacrificial gate structure. The interfacial layer can be deposited by any suitable techniques, such as ALD, CVD, PVD, thermal oxidation, combinations thereof, or other suitable techniques.

In some examples, the gate 154 may be formed by forming a high-κlayer to cover the exposed surfaces of the interfacial layer. The high-κlayer can be deposited by any suitable techniques, such as ALD, CVD, metal-organic CVD (MOCVD), PVD, thermal oxidation, combinations thereof, or other suitable techniques. A high-κmaterial is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The gate 154 can include a single layer or multiple layers, such as metal layer, liner layer, wetting layer, and adhesion layer. In other embodiments, the gate 154 can include, e.g., workfunction metals and optional conductive metals, such as Ti, Ag, Al, TiAlN, TaC, TaCN, TaSiN, Mn, Zr, TiN, TaN, Ru, Mo, Al, WN, Cu, W, or any suitable materials. The metal(s) can be deposited by a suitable deposition process, for example, chemical vapor deposition (CVD), plasma enhanced chemical vapor deposition (PECVD), physical vapor deposition (PVD), plating, thermal or e-beam evaporation, or sputtering. The WF gate may set the threshold voltage (Vt) of the device.

After the gate 154 formation, the top surface of the semiconductor IC device 100 may be planarized by a planarization technique such as a CMP, mechanical grinding process, or the like.

In some examples, the FEOL 110 section includes the semiconductor IC device 100 portion generally below the top surface of the gate 154.

The MOL includes frontside contacts 160, 162, 164 that connect the FEOL 110 and a frontside BEOL network 112 and further includes material(s) to prevent the diffusion of frontside BEOL network 112 conductive material(s) into FEOL active devices (e.g., FETs 150). After gate planarization, an ILD may be formed over the gate 154 by depositing a dielectric material, such as, for example, porous silicates, carbon doped oxides, silicon dioxides, silicon nitrides, silicon oxynitrides, or other dielectric materials. Any appropriate deposition technique for forming the ILD can be utilized. The ILD can be formed using, for example, CVD, PECVD, ALD, flowable CVD, spin-on dielectrics, or PVD.

The frontside contact(s) 160, 162, 164 may be formed by patterning respective frontside contact openings within ILD from the frontside (i.e., from above the semiconductor IC device 100, as depicted, downward to respective structures thereof). The frontside contact(s) 160, 162, 164 may be in direct or indirect physical and electrical contact and/or may physically meld with respective material(s) of one or more regions of the semiconductor IC device 100. For example, frontside contact 162 is in direct contact with gate 154, frontside contact 164 is in direct contact with S/D region 142, or the like,

The frontside contact(s) 160, 162, 164 may be formed by initially forming frontside contact opening(s). The frontside contact opening(s) may be formed by the same or shared lithography and etch process(es), or sequential lithography and etch processes. In such process(es), a mask may be applied and patterned. An opening in the patterned mask may expose the portion of the underlying ILD to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The frontside contact(s) 160, 162, 164 may be further formed by depositing conductive material such as metal into the respective frontside contact opening(s). In an example, frontside contact(s) 160, 162, 164 may be formed by depositing a liner, such as Ni, NiPt or Ti, etc. into the contact opening(s), depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective top surfaces of frontside contact(s) 160, 162, 164 and the ILD may be coplanar.

The frontside BEOL network 112 includes contacts, insulating layers (e.g., dielectrics, or the like), metal levels, and conductive pads for chip-to-package connections. In the frontside BEOL network 112 fabrication stages, sequential metal levels (e.g., M.0 through M.6, as depicted) of a respective dielectric layer having one or more conductive wires therein are formed. A particular wire within the metal levels may be chosen to be a charge collector wire 170. Sequential via levels (e.g., V.1 through V.6) of a respective dielectric layer having one or more conductive via interconnects therein are formed to connect the predetermined conductive wires located within metal levels there above and there below. The metal levels, via levels, and associated dielectric layer(s) may be formed, for example, using single damascene or dual-damascene processes. A lowest via level (e.g., V.0) may connect the frontside BEOL network 112 to the MOL frontside contact(s) 160, 162, 164. For example, a via 168 may connect the frontside contact 160 and the charge collector wire 170, a via 169 may connect the gate 154 to the charge collector wire 170. A conductive pathway 172 may consist of various conductive wires within the metal levels and interconnect vias within the via levels that is electrically connected to the charge collector. Alternatively, the conductive pathway 172 may consist of a deep via connected to the charge collector wire 170 and may extend there above through the frontside BEOL network 112.

For clarity, at the present fabrication stage, a particular conductive path or node exists within semiconductor IC device 100 and may consist of the conductive pathway 172, the charge collector wire 170, the via 168, frontside contact 160, and doped region 140. The particular conductive path or node further consists of the via 169, the frontside contact 162, and the gate 154 by way of the charge collector wire 170.

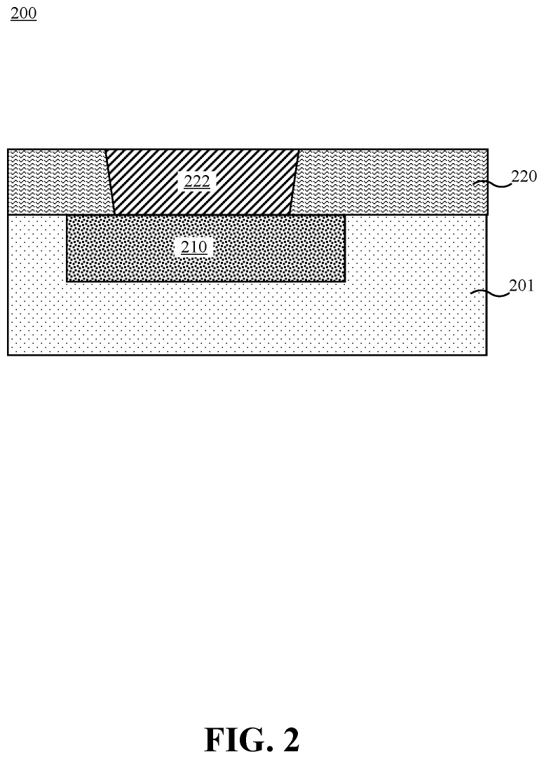

Referring now to FIG. 2, which depicts an illustrative handler semiconductor IC device 200, at a particular fabrication stage. At the present fabrication stage, the handler semiconductor IC device 200 includes a handler substrate 201, a diode doped region 210, an ILD 220, and diode contact 222.

The handler substrate 201 may be comprised of any suitable material(s), such as those listed above with regards to the substrate structure of FIG. 1, the descriptions of which are not repeated herein, in addition to one or more doped regions for diode formation. The diode doped region 210 may be formed by techniques and comprised of any suitable material(s), such as those listed above with regards to doped region 140, the descriptions of which are not repeated herein.

ILD 220 may be formed over the handler substrate 201 and the diode doped region 210 by depositing a dielectric material, such as, for example, porous silicates, carbon doped oxides, silicon dioxides, silicon nitrides, silicon oxynitrides, or other dielectric materials. Any appropriate deposition technique for forming the ILD 220 can be utilized. The ILD 220 can be formed using, for example, CVD, PECVD, ALD, flowable CVD, spin-on dielectrics, or PVD.

The diode contact 222 may be formed by patterning respective contact openings within ILD 220. The diode contact 222 may be in direct or indirect physical and electrical contact and/or may physically meld with respective material(s) of diode doped region 210. For example, diode contact 222 is in direct contact with diode doped region 210.

The diode contact 222 may be formed by initially forming a contact opening. The contact opening may be formed by lithography and etch process(es). In such process(es), a mask may be applied and patterned. An opening in the patterned mask may expose the portion of the underlying ILD 220 to be removed while other protected portions of semiconductor IC device 200 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The diode contact 222 may be further formed by depositing conductive material such as metal into the contact opening. In an example, diode contact 222 may be formed by depositing a liner, such as Ni, NiPt or Ti, etc. into the contact opening, depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective top surfaces of frontside diode contact 222 and the ILD 220 may be coplanar.

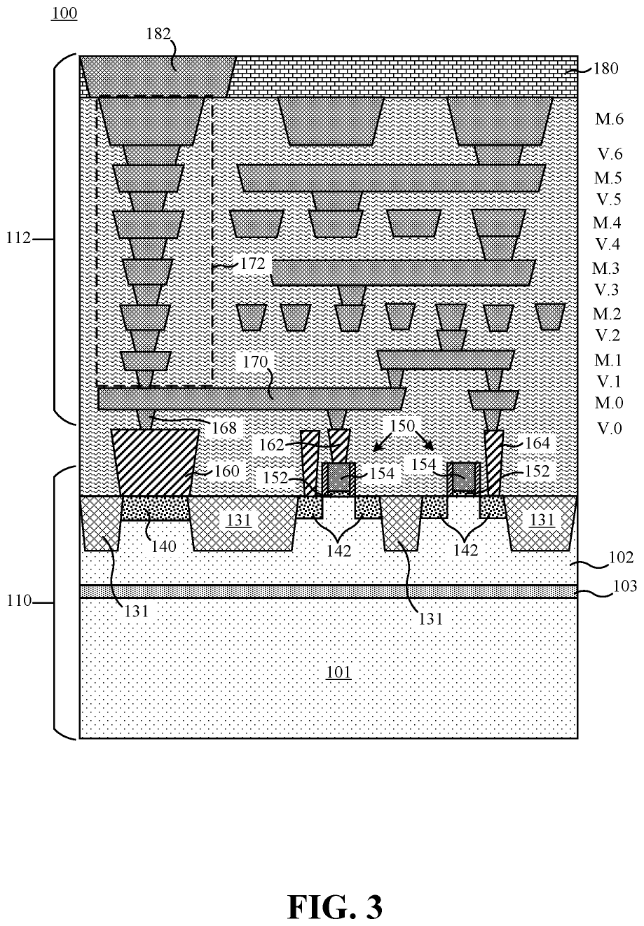

Referring now to FIG. 3, which depicts the active semiconductor IC device 100, at a particular fabrication stage. At the present fabrication stage, a bonding dielectric layer(s) 180 and a first conductive pad 182 are formed upon the active semiconductor IC device 100.

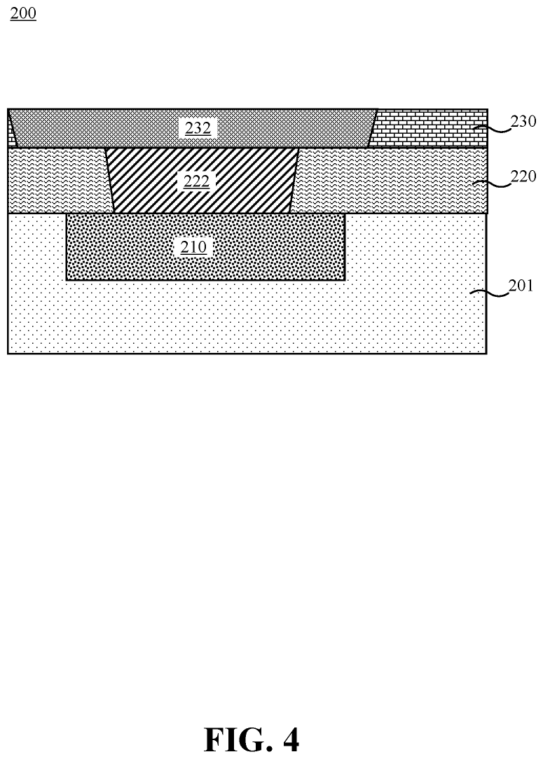

The bonding dielectric layer 180 can be formed on the frontside or top surface of the semiconductor IC device 100 of FIG. 1 by a blanket deposition, for example, chemical vapor deposition (CVD) or plasma enhanced CVD (PECVD). The bonding dielectric layer 180 can be a dielectric material layer, for example, silicon oxide (SiO), silicon nitride (SiN), etc., that can allow the bonding dielectric layer 230, depicted in FIG. 4, to be secured to the bonding dielectric layer 180 through a bonding process, such as oxide-oxide bonding, nitride-nitride bonding, or the like.

The first conductive pad 182 may be in direct or indirect physical and electrical contact and/or may physically meld with respective conductive material(s) of conductive pathway 172. For example, the first conductive pad 182 is in direct contact with the wire in the topmost (e.g., M.6) metal level.

The first conductive pad 182 may be formed by initially forming a pad opening. The pad opening may be formed by lithography and etch process(es). In such process(es), a mask may be applied and patterned. An opening in the patterned mask may expose the portion of the underlying active semiconductor IC device 100 to be removed while other protected portions of active semiconductor IC device 100 thereunder may be protected and retained. In such process(es), the dry and/or wet etching processes can have etching parameters that can be tuned, such as etchants used, etching temperature, etching solution concentration, etching pressure, source power, RF bias voltage, RF bias power, etchant flow rate, to promote desired material removal and desired material retention.

The first conductive pad 182 may be further formed by depositing conductive material such as metal into the pad opening. In an example, first conductive pad 182 may be formed by depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive material(s). Subsequently, the respective top surfaces of the first conductive pad 182 and the bonding dielectric layer 180 may be coplanar.

Referring now to FIG. 4, which depicts the handler semiconductor IC device 200, at a particular fabrication stage. At the present fabrication stage, a bonding dielectric layer(s) 230 and a second conductive pad 232 are formed upon the handler semiconductor IC device 200.

The bonding dielectric layer 230 can be formed on the frontside or top surface of the handler semiconductor IC device 200 of FIG. 2 by a blanket deposition, for example, chemical vapor deposition (CVD) or plasma enhanced CVD (PECVD). The bonding dielectric layer 230 can be a dielectric material layer, for example, silicon oxide (SiO), silicon nitride (SiN), etc., that can allow the bonding dielectric layer 180, depicted in FIG. 3, to be secured to the bonding dielectric layer 230 through a bonding process, such as oxide-oxide bonding, nitride-nitride bonding, or the like.

The second conductive pad 232 may be formed by patterning respective pad openings within the bonding dielectric layer 230. The second conductive pad 232 may be in direct or indirect physical and electrical contact and/or may physically meld with respective conductive material(s) of frontside diode contact 222. For example, the second conductive pad 232 is in direct contact with the frontside diode contact 222.

The second conductive pad 232 may be formed by similar techniques relative to first conductive pad 182 and further details are not repeated herein. Subsequently, a planarization process, such as a CMP process or a mechanical grinding process, may remove excess portions of the second conductive pad 232. Subsequently, the respective top surfaces of the second conductive pad 232 and the bonding dielectric layer 230 may be coplanar.

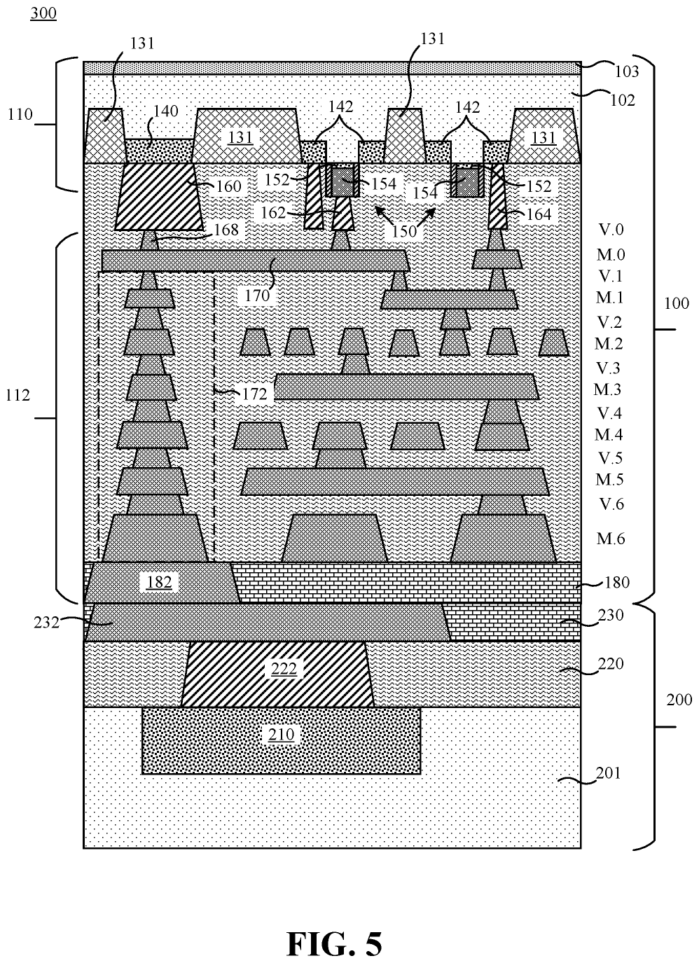

Referring now to FIG. 5, which depicts a semiconductor IC device 300, at a particular fabrication stage. At the present fabrication stage, the semiconductor IC device 300 is formed by bonding the active semiconductor IC device 100 to the handler semiconductor IC device 200. Further in the present fabrication stage, the lower substrate 101 of the active semiconductor IC device 100 is removed.

The active semiconductor IC device 100 is aligned and faced with respect to the handler semiconductor IC device 300 so that at least a portion of the second conductive pad 232 and the first conductive pad 182 may overlap and face one another. A frontside or top surface of the handler semiconductor IC device 300 and/or the (now depicted) bottom surface of the active semiconductor IC device 100 may be covered with a thin layer of adhesive to facilitate the bonding thereof. The combined semiconductor IC device 300 may be annealed (e.g., at a temperature of 200° C. to 300° C.), thereby creating a covalent bond between the bonding dielectric layer 180 and the bonding dielectric layer 230 and a physical contacting between or melding bond between the second conductive pad 232 and the first conductive pad 182.

The lower substrate 101 may be removed using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the (now depicted) top surface of etch stop layer 103.

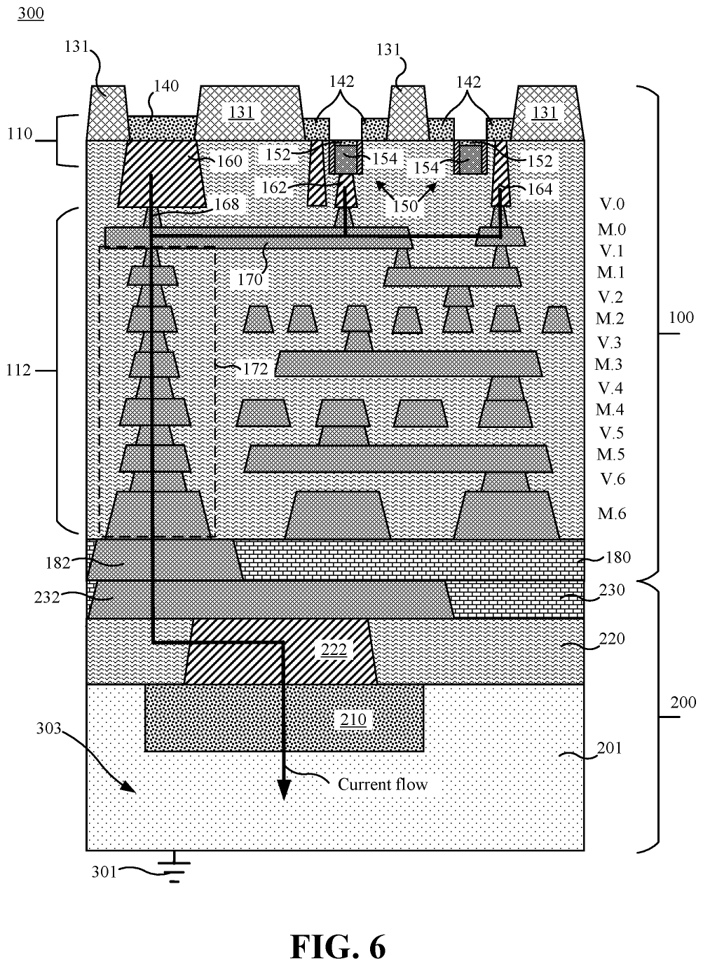

Referring now to FIG. 6, which depicts the semiconductor IC device 300 at another fabrication stage. At the present fabrication stage, the remaining substrate structure is removed. For example, etch stop layer 103 and the upper substrate 102 may be removed.

The etch stop layer 103 may be removed by a subtractive removal technique such as a CMP, dry and/or wet etch. Upon removal of the etch stop layer 103, the upper substrate 102 is exposed. The removal of etch stop layer 103 may be selective to the material of upper substrate 102. For example, etch stop layer 103 is removed by an etch that utilizes upper substrate 102 as the etch stop.

Subsequently, the upper substrate 102 is removed by an appropriate substrative removal technique, such as an etch, that removes associated portion(s) of the upper substrate 102. The etch may be timed or otherwise controlled to remove the material of the upper substrate 102 and retain or otherwise expose the STI regions 131, retain and partially expose doped region 140, and retain and partially expose S/D region(s) 142.

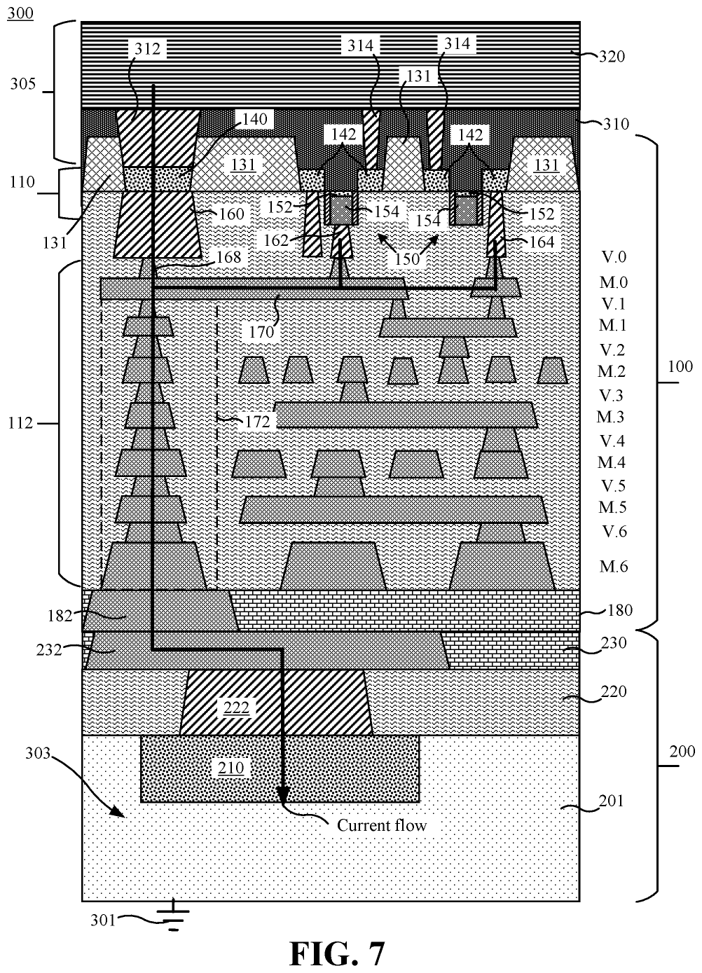

In some implementations, the removal of etch stop layer 103 and/or the upper substrate 102 may be completed by plasma etching processes. Plasma etching can lead to charge buildup within the semiconductor IC device 300. For example, this plasma etching can lead to charge buildup in gate 154 and, if sufficiently high, the charge buildup can lead to damage to the gate isolation 152 associated therewith, reducing semiconductor IC device 300 yield, causing semiconductor IC device 300 failure, or the like. However, one or more embodiments of the disclosure provide for an antenna diode 303 within handler semiconductor IC device 200 that is integrated with a backside (e.g., backside 305 as depicted in FIG. 7) of active semiconductor IC device 100 to drain such parasitic charge buildup.

More specifically, when a potential 301 is applied to substrate 201 (e.g., a VSS or ground potential is applied, the semiconductor IC device is grounded, etc.) of the handler semiconductor IC device 200, the antenna diode 303 is formed by the diode doped region 210 (e.g., a heavily P doped region, or the like), the substrate 201, and the potential 301. For example, a PIN type antenna diode is formed by the diode doped region 210, the substrate 201, and the potential 301.

During the present or previous fabrication stage(s) to remove the substrate structure, such potential 301 may be applied to the handler semiconductor IC device 200. Charge build up that may occur within doped region 140, within gate 154, and/or within frontside contact(s) 162, 164, or the like, may be effectively passed to and collected on the charge collector wire 170 and further dissipated through the antenna diode 303. As such, parasitic charge build up that may damage the semiconductor IC device 300 may be limited, thereby increasing yield thereof.

Referring now to FIG. 7, which depicts the semiconductor IC device 300 at another fabrication stage. At the present fabrication stage, backside ILD 310 is formed upon the exposed backside 305 of the active semiconductor IC device 100, backside contacts 312, 314, or the like are formed within the backside ILD 310, and a backside BEOL network 320 is formed.

The backside ILD 310 may be formed over the gate(s) and upon the exposed portions(s) of the STI regions 131, the exposed portions(s) of the doped region 140, and the exposed portions(s) of the S/D region(s) 142. The backside ILD 310 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 310 can be utilized. The backside ILD 310 can be formed using, for example, CVD, PECVD, ALD, flowable CVD, spin-on dielectrics, or PVD. In an example, the backside ILD 310 may be formed to a thickness above (as depicted) the top surface of the STI regions.

The backside contacts 312, 314 may be formed by initially forming backside contact openings within backside ILD 310. The backside contact openings may be formed by the same or shared lithography and etch process(es), or sequential lithography and etch processes. In such process(es), a mask may be applied to the backside of the backside ILD 310 and patterned. Openings in the patterned mask may expose the portion of the underlying backside ILD 310 to be removed while other protected portions of semiconductor IC device 300 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

In the depicted example, a backside contact opening may be formed within backside ILD 310 to expose a portion of the doped region 140, a backside contact opening may be formed within backside ILD 310 to expose a portion of a particular S/D region 142, or the like.

The backside contacts 312, 314 are formed within the backside contact openings. For clarity, a particular backside contact 312 is positionally located so as to be connected with doped region 140 and respective backside contacts 314 are positionally located so as to be connected with a respective S/D region 142.

The backside contacts 312, 314 may be formed by depositing conductive material, such as metal, into the respective backside contact openings. For example, backside contacts 312, 314 may be formed by depositing a liner, such as Ni, NiPt or Ti, etc. into the backside contact openings, depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective top surfaces (as depicted) of backside contacts 312, 314 and backside ILD 310 may be substantially horizontal and/or substantially coplanar.

The backside BEOL network 320 is formed over the backside ILD 310 and upon the one or more backside contacts 312, 314. The backside BEOL network 320 may be indirectly electrically and/or indirectly physically connected to the one or more S/D regions 142 and the doped region 140 by way of a particular backside contact 312, 314, respectively. As depicted, the backside BEOL network 320 may be positioned or located directly on the backside surface of backside ILD 310, backside contacts 312, 314, etc.

The backside BEOL network 320 can include one or more interconnect dielectric material layers (including one of the dielectric materials mentioned above) and contains backside metal wires embedded therein. In some embodiments, the backside metal wires within the backside BEOL network 320 are composed of Cu. The backside BEOL network 320 can include “x” numbers of frontside metal levels, wherein “x” is an integer starting from 1. The backside BEOL network 320 may further contain conductive pads that are connected to one or more of the backside metal wires and may be used to connect the semiconductor IC device 300 to an external and/or higher-level structure, such as a carrier or motherboard.

In an example, signal routing and power routing is effectively split between the frontside BEOL network 112 and the backside BEOL network 320. For example, at least 90% of the frontside metal wires (e.g., furthest from the transistor(s)) are signal routing metal wires and the remainder frontside metal wires which are usually present in metal levels closest to the transistor, can be used as power routing wires. Further in this example, at least 90% of the backside metal wires that are in metal levels closest to the transistor(s) are power routing metal wires and the remainder backside metal wires which are usually present in metal levels furthest away from the transistor, can be used as signal routing wires. Power routing wires may be less dense signal routing wires. A signal routing wire is defined herein as a conductive feature, such as a wire, trace, or the like, that is configured to electrically carry a functional or logical potential or signal that is to change or is otherwise dynamic over time. A power routing wire is defined herein as a conductive feature, such as a wire, trace, plane, or the like, that is configured to electrically carry a logical potential that does not change over a predetermined time. For example, a power routing wire carries or otherwise has a functional power potential, such as VDD, VSS, or the like. For clarity, in some examples, the backside BEOL network 320 may be a backside power distribution network (BSPDN).

In some implementations, the removal of portions of the interconnect dielectric material layers to form the conductive features (e.g., wires, vias, etc.) within the backside BEOL network 320 may be completed by plasma etching processes. Plasma etching can lead to charge buildup within the semiconductor IC device 300. For example, this plasma etching can lead to charge buildup in gate 154 and if sufficiently high, the charge buildup can lead to damage to the gate isolation 152 associated therewith, reducing semiconductor IC device 300 yield, causing semiconductor IC device 300 failure, or the like. However, the antenna diode 303 within handler semiconductor IC device 200 that is integrated with the backside of active semiconductor IC device 100 drains such parasitic charge buildup.

More specifically, during the etching process(es), the potential 301 is applied to substrate 201 (e.g., a VSS or ground potential is applied, the semiconductor IC device is grounded, etc.) of the handler semiconductor IC device 200 and the antenna diode 303 is formed.

During the present or previous fabrication stage(s) fabricate the backside BEOL network 320, such potential 301 may be applied to the handler semiconductor IC device 200. Charge build up that may occur within doped region 140, within gate 154, and/or within frontside contact(s) 162, 164, or the like, may be effectively passed to and collected on the charge collector wire 170 and further dissipated through the antenna diode 303. As such, parasitic charge build up that may damage the semiconductor IC device 300 may be limited, thereby increasing yield thereof.

Semiconductor IC device 300 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

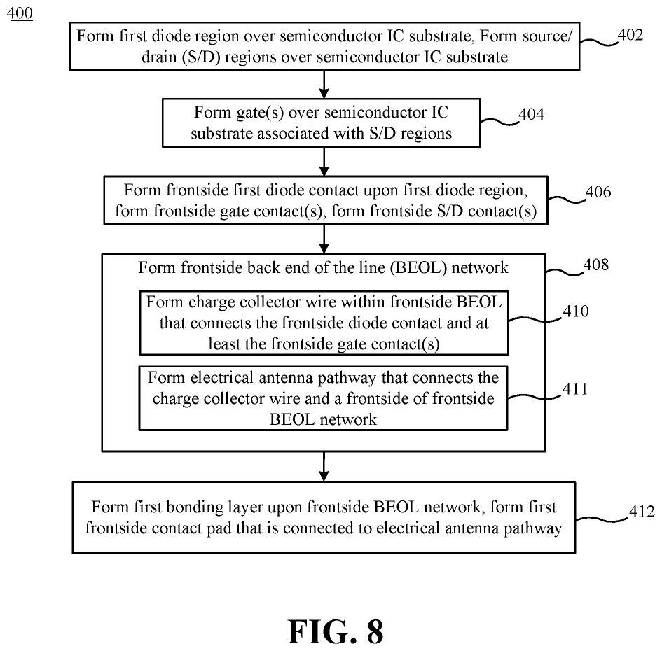

FIG. 8 depicts a flow diagram illustrating method 400 to fabricate a semiconductor IC device, such as active semiconductor IC device 100. The depicted fabrication operations of method 400 are illustrated and described above with reference to one or more of FIG. 1 through FIG. 4 of the drawings, which describe the fabrication of handler semiconductor IC device 200 and the fabrication of active semiconductor IC device 100, though the fabrication operations described in method 400 may be used to fabricate other types of semiconductor IC devices. The method 400 depicted herein is illustrative. There can be many variations to the diagram or operations described therein without departing from the spirit of the embodiments. For instance, the operations can be performed in a differing order, or operations can be added, deleted, or modified.

At block 402, method 400 may begin with forming a diode region over a semiconductor substrate and/or forming one or more source/drain (S/D) regions over the semiconductor substrate. For example, a diode region 140 and S/D regions 142 may be formed over or within the upper substrate 102 of the substrate structure.

At block 404, method 400 may continue with forming one or more gates over the semiconductor substrate in association with the one or more S/D regions. For example, one or more gates 154 may be formed upon or around one or more channel regions formed from or formed over the substrate structure. In this manner, a transistor that includes a gate, channel, and S/D regions may be formed.

At block 406, method 400 may continue with forming a frontside diode contact upon the diode region, with forming one or more frontside gate contacts upon respective gate(s), and with forming frontside S/D contacts upon respective source regions and drains regions. For example, frontside diode contact 160 is formed upon the diode region 140, a respective frontside gate contact 162 is formed upon the one or more gate(s) 154, and a respective frontside S/D contact 164 is formed upon respective S/D regions 142.

At block 408, method 400 may continue with forming a frontside BEOL network. For example, frontside BEOL network 112 is formed. In the frontside BEOL network, a charge collector wire is formed that directly or indirectly connects the frontside diode connector and at least one of the frontside gate contact(s) (block 410). The charge collector wire may further be directly or indirectly connected to one or more frontside S/D contact(s). For example, within the frontside BEOL network 112, charge collector wire 170 is formed that is electrically connected to the frontside diode contact 160, one or more frontside gate contacts 162, and may further be electrically connected to one or more frontside S/D contacts 164. Further in the frontside BEOL network, an electrical antenna pathway is formed that directly or indirectly connects the charge collector wire and a frontside of the frontside BEOL network (block 411). For example, electrical pathway 172 is formed that connects charge collector wire 170 to the frontside (e.g., top surface as depicted in FIG. 1) of the frontside BEOL network 112.

At block 412, method 400 may continue with forming a bonding layer upon the frontside BEOL network, with forming a first frontside contact pad that is connected to the electrical antenna pathway. For example, bonding dielectric layer 180 is formed upon the frontside BEOL network 112 and contact pad 182 that is connected to electrical antenna pathway 172 is formed within the bonding dielectric layer 180.

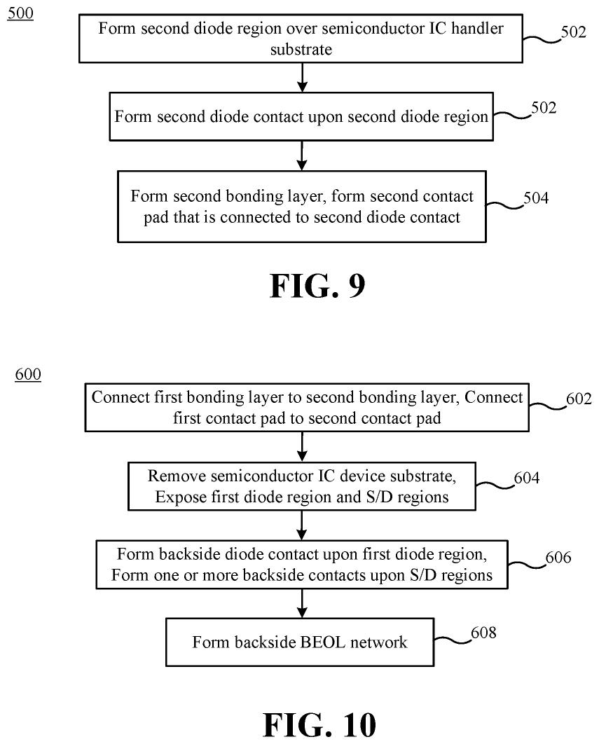

FIG. 9 depicts a flow diagram illustrating method 500 to fabricate a semiconductor IC device, such as handler semiconductor IC device 200. The depicted fabrication operations of method 500 are illustrated and described above with reference to one or more of FIG. 2 through FIG. 4 of the drawings, which describe the fabrication of the handler semiconductor IC device 200 and the fabrication of active semiconductor IC device 100, though the fabrication operations described in method 500 may be used to fabricate other types of semiconductor IC devices. The method 500 depicted herein is illustrative. There can be many variations to the diagram or operations described therein without departing from the spirit of the embodiments. For instance, the operations can be performed in a differing order, or operations can be added, deleted, or modified.

At block 502, method 500 may begin with forming a diode region over a semiconductor IC handler substrate. For example, diode doped region 210 is formed within handler substrate 201. In a particular embodiment, the diode doped region 210 is a heavily p-type (i.e., P+) doped region.

At block 504, method 500 may continue with forming an ILD layer upon the frontside of the handler substrate and/or with forming a diode contact upon the diode region. For example, an ILD 220 may be formed upon the handler substrate 201 and upon the diode doped region 210 and the frontside diode contact 222 may be formed upon the diode doped region 210 within the ILD 220.

At block 506, method 500 may continue with forming a bonding layer upon the frontside of the semiconductor IC device and with forming a frontside contact pad that is connected to the diode contact. For example, bonding dielectric layer 230 is formed upon the frontside of the handler semiconductor IC device 200 and contact pad 232, that is connected to diode region 210, is formed within the bonding dielectric layer 230.

FIG. 10 depicts a flow diagram illustrating method 600 to fabricate a semiconductor IC device, such as semiconductor IC device 300. The depicted fabrication operations of method 600 are illustrated and described above with reference to one or more of FIG. 5 through FIG. 7 of the drawings, which describe the fabrication of the semiconductor IC device 300, though the fabrication operations described in method 600 may be used to fabricate other types of semiconductor IC devices. The method 600 depicted herein is illustrative. There can be many variations to the diagram or operations described therein without departing from the spirit of the embodiments. For instance, the operations can be performed in a differing order, or operations can be added, deleted, or modified.

At block 602, method 600 may begin with connecting the bonding layer of the active semiconductor IC device with the bonding layer of the handler semiconductor IC device and with connecting the contact pad of the active semiconductor IC device with the contact pad of the handler semiconductor IC device. For example, the active semiconductor IC device 100 is aligned and connected to the handler semiconductor IC device 200 (e.g., bonding dielectric layer 180 is bonded to bonding dielectric layer 230) with first conductive pad 182 making contact, melding, or bonding with second conductive pad 232.

At block 604, method 600 may continue with removing the substrate structure of the active semiconductor IC device and at least partially exposing respective backsides of the diode region and the S/D regions of the active semiconductor IC device. For example, lower substrate 101, etch stop layer 103, and upper substrate 102 is removed, thereby at least partially exposing the diode region 140 and the S/D regions 142.

At block 606, method 600 may continue with forming a backside diode contact upon the diode region and with forming one or more other backside contacts (e.g., backside S/D contact(s), or the like). For example, backside ILD 310 is formed upon the partially exposed the diode region 140, the S/D regions 142, or the like. Subsequently, backside contact 312 is formed in contact with the diode region 140 and a backside S/D contact 314 is formed in contact with one or more S/D regions 142 within the backside ILD 310.

At block 608, method 600 may continue with forming a backside BEOL network. For example, backside BEOL network 320 is formed upon the backside of semiconductor IC device 300. One or more respective wires or other conductive features within the backside BEOL network 320 may be electrically connected with the backside contact 312, with the one or more S/D contacts 314, or the like.

During the fabrication stage(s) of method 600 associated with the exposing of the diode region 140 and/or the exposing of the S/D regions 142 and with fabricate the backside BEOL network 320, a potential may be applied to the handler semiconductor IC device 200. As a result of such potential, handler substrate 201, and the diode doped region 210, and antenna diode 303 is formed. During such fabrication stage(s), charge build up that may occur within doped region 140, within gate 154, and/or within frontside contact(s) 162, 164, or the like, may be effectively passed to and collected on the charge collector wire 170 and further dissipated through the antenna diode 303. As such, parasitic charge build up that may damage the semiconductor IC device 300 may be limited, thereby increasing yield thereof.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a handler semiconductor IC device comprising: a diode doped region; and
an active semiconductor IC device comprising:
a backside source/drain (S/D) contact connected to a S/D region;
a backside diode contact electrically connected to the diode doped region.

2. The semiconductor IC device of claim 1, wherein the active semiconductor IC device further comprises a frontside back end of line (BEOL) network with a charge collector wire connected to the diode doped region.

3. The semiconductor IC device of claim 2, wherein the active semiconductor IC device further comprises a frontside gate contact connected to the diode doped region through the charge collector wire.

4. The semiconductor IC device of claim 2, wherein the active semiconductor IC device further comprises a frontside S/D contact connected to the diode doped region through the charge collector wire.

5. The semiconductor IC device of claim 2, wherein the active semiconductor IC device further comprises a first contact pad connected to the charge collector wire.

6. The semiconductor IC device of claim 1, wherein the handler semiconductor IC device further comprises a second contact pad connected to the diode doped region.

7. The semiconductor IC device of claim 2, wherein electrical charge within the charge collector flows in a direction towards and dissipates through the diode doped region.

8. The semiconductor IC device of claim 5, wherein the active semiconductor IC device further comprises an electrical pathway connected to the charge collector wire and connected to the first contact pad, the electric pathway comprising a plurality of conductive wires and a plurality of conductive vias.

9. The semiconductor IC device of claim 6, wherein the handler semiconductor IC device further comprises a diode contact between the second contact pad and the diode doped region.

10. A semiconductor integrated circuit (IC) device comprising:
an antenna diode within a handler semiconductor IC device, the antenna diode comprising a diode doped region; and
an active semiconductor IC device comprising a backside source/drain (S/D) contact connected to a S/D region and a backside diode contact connected to the diode doped region.

11. The semiconductor IC device of claim 10, wherein the active semiconductor IC device further comprises a frontside back end of line (BEOL) network with a charge collector wire connected to the diode doped region.

12. The semiconductor IC device of claim 11, wherein the active semiconductor IC device further comprises a frontside gate contact connected to the diode doped region through the charge collector wire.

13. The semiconductor IC device of claim 11, wherein the active semiconductor IC device further comprises a frontside S/D contact connected to the diode doped region through the charge collector wire.

14. The semiconductor IC device of claim 11, wherein the active semiconductor IC device further comprises a first contact pad connected to the charge collector wire.

15. The semiconductor IC device of claim 10, wherein the handler semiconductor IC device further comprises a second contact pad connected to the diode doped region.

16. The semiconductor IC device of claim 11, wherein electrical charge within the charge collector flows in the direction and dissipates through the antenna diode.

17. The semiconductor IC device of claim 14, wherein the active semiconductor IC device further comprises an electrical pathway connected to the charge collector wire and connected to the first contact pad, the electric pathway comprising a plurality of conductive wires and a plurality of conductive vias.

18. The semiconductor IC device of claim 15, wherein the handler semiconductor IC device further comprises a diode contact between the second contact pad and the diode doped region.

19. A semiconductor integrated circuit (IC) device fabrication method comprising:
bonding a handler semiconductor IC device to an active semiconductor device;
forming a backside back end of line (BEOL) network over a backside of the active semiconductor device; and
dissipating electrical charge through a frontside BEOL network of the active semiconductor device and further through the handler semiconductor IC device.

20. The semiconductor IC device fabrication method of claim 19, wherein the electrical charge is dissipated through a diode doped region within the handler semiconductor IC device.
